(19) United States
(12) Patent Application Publication
(10) Pub. No.: US 2005/0189634 A1
(43) Pub. Date: Sep. 1, 2005

(54) Semiconductor module and method of manufacturing thereof

(75) Inventors: Satoru Wakiyama, Hyogo (JP); Shinji Baba, Hyogo (JP)

Correspondence Address: MCDERMOTT WILL & EMERY LLP, 600 13TH STREET, N.W., WASHINGTON, DC, 20005-3096, US

(73) Assignee: RENESAS TECHNOLOGY CORP.

(21) Appl. No.: 11/063,610

(22) Filed: Feb. 24, 2005

(30) Foreign Application Priority Data
Mar. 1, 2004 (JP) 2004-056063(P)

(51) Int. Cl. H01L 23/02

(52) U.S. Cl. 257/678

(57) ABSTRACT

A method of manufacturing a semiconductor module includes the steps of producing semiconductor devices of substantially the same thickness by forming respective resin portions covering respective semiconductor elements, mounting the semiconductor devices on a module substrate, covering inner bumps of the semiconductor devices with an encapsulating resin, providing a heat radiation plate over the semiconductor devices, and providing external electrodes on the rear surface of the module substrate.

### BACKGROUND OF THE INVENTION

1. Field of the Invention

The present invention relates to a semiconductor module and a method of manufacturing the semiconductor module. In particular, the invention relates to a semiconductor module having semiconductor elements that are different in thickness and a method of manufacturing the semiconductor module.

2. Description of the Background Art

A semiconductor module having a plurality of semiconductor devices (like CSP (Chip Scale Package) and SiP (System in Package)) on a module substrate has been known.

Japanese Patent Laying-Open No. 2001-094013 for example discloses that chips used for the CSP are manufactured, an electrical test is then performed on the manufactured chips, CSP chips that pass the test are packaged in strip form, the CSPs in strip form are electrically tested again and separated into individual CSPs, and the separate CSPs are surface-mounted on a module board and thereafter subjected to a burn-in test in the form of the module board.

The above-described manufacturing method of a semiconductor module, however, has the following problem.

It could occur that a plurality of semiconductor devices that are components of a semiconductor module are different in thickness, for example, when semiconductor elements (chips) in CSPs have respective thicknesses different from each other.

In such a case in which semiconductor devices that are components of one semiconductor module are different in thickness from each other, a heat radiation plate to be provided on the semiconductor devices has to be divided or the heat radiation plate has to be shaped into a complicated form, resulting in a complicated assembly process of the semiconductor module.

### SUMMARY OF THE INVENTION

An object of the present invention is to provide a semiconductor module and a method of manufacturing the semiconductor module with a simplified manufacturing process.

A method of manufacturing a semiconductor module according to the present invention includes the steps of: producing a first semiconductor device by forming a first resin portion on a first semiconductor element; producing a second semiconductor device substantially identical in thickness to the first semiconductor device by forming a second resin portion on a second semiconductor element different in thickness from the first semiconductor element; mounting the first semiconductor device and the second semiconductor device on a module substrate; and providing an external electrode on a rear surface of the module substrate.

Further, a semiconductor module according to the present invention includes: a module substrate; an external electrode on a rear surface of the module substrate; a first semiconductor device having on the module substrate a first semiconductor element with a first thickness and a first resin portion on the first semiconductor element; and a second semiconductor device substantially identical in thickness to the first semiconductor device and having on the module substrate a second semiconductor element with a second thickness different from the first thickness and a second resin portion on the second semiconductor element.

According to the present invention, the process of manufacturing a semiconductor module having a plurality of semiconductor elements that are different in thickness from each other can be simplified.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIGS. 1A and 1B are cross sections illustrating a first step of a process of manufacturing a semiconductor module according to first and second embodiments of the present invention, with FIG. 1A showing a cross section of a first semiconductor element and FIG. 1B showing a cross section of a second semiconductor element.

FIGS. 2A and 2B are cross sections illustrating a second step of the process of manufacturing a semiconductor module according to the first embodiment of the present invention, with FIG. 2A showing a cross section of a first semiconductor device and FIG. 2B showing a cross section of a second semiconductor device.

FIGS. 3 to 5 are cross sections respectively illustrating third to fifth steps of the process of manufacturing the semiconductor module according to the first embodiment of the present invention.

FIG. 6 is a cross section of the semiconductor module according to the first embodiment of the present invention.

FIG. 7 is a plan view of an example of the state shown in FIG. 3 in the process of manufacturing the semiconductor module according to the first embodiment of the present invention.

FIG. 8 is a plan view of another example of the state shown in FIG. 3 in the process of manufacturing the semiconductor module according to the first embodiment of the present invention.

FIG. 9 is a plan view of still another example of the state shown in FIG. 3 in the process of manufacturing the semiconductor module according to the first embodiment of the present invention.

FIGS. 10A to 10C are cross sections illustrating a second step subsequent to the step shown in FIG. 1 in the process of manufacturing a semiconductor module according to the second embodiment of the present invention, with FIGS. 10A to 10C showing respective cross sections of a first semiconductor device, a second semiconductor device and a third semiconductor device.

FIGS. 11 to 13 are cross sections respectively illustrating third to fifth steps of the process of manufacturing the semiconductor module according to the second embodiment of the present invention.

FIG. 14 is a cross section of the semiconductor module according to the second embodiment of the present invention.

FIG. 15 is a flowchart showing a method of manufacturing a semiconductor module according to the first and second embodiments of the present invention.

### DESCRIPTION OF THE PREFERRED EMBODIMENTS

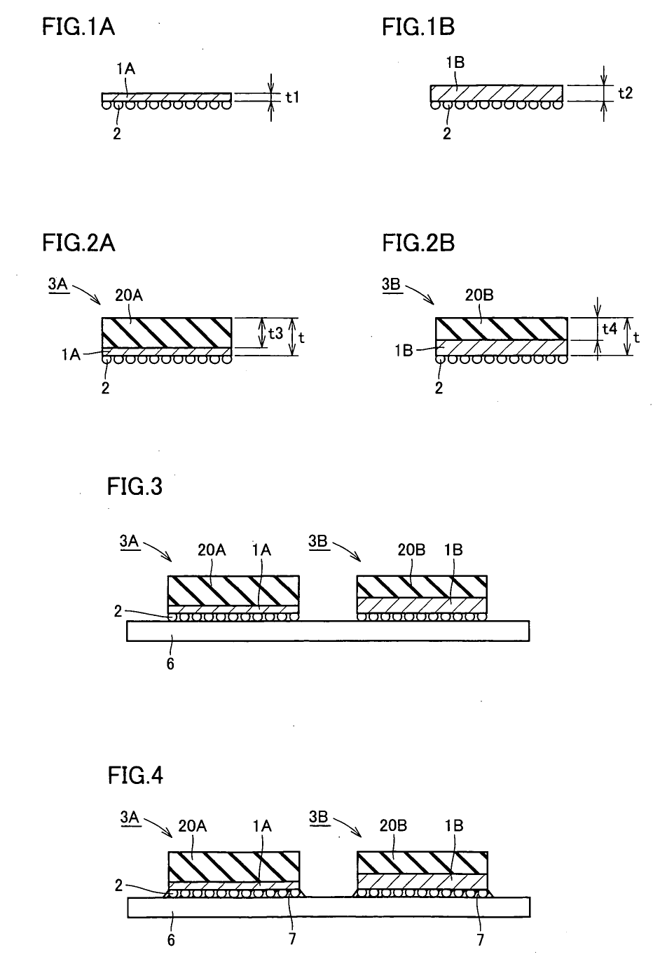

With reference to FIGS. 1A, 1B to 15, embodiments of a semiconductor module and a manufacturing method thereof in accordance with the present invention are hereinafter described.

### First Embodiment

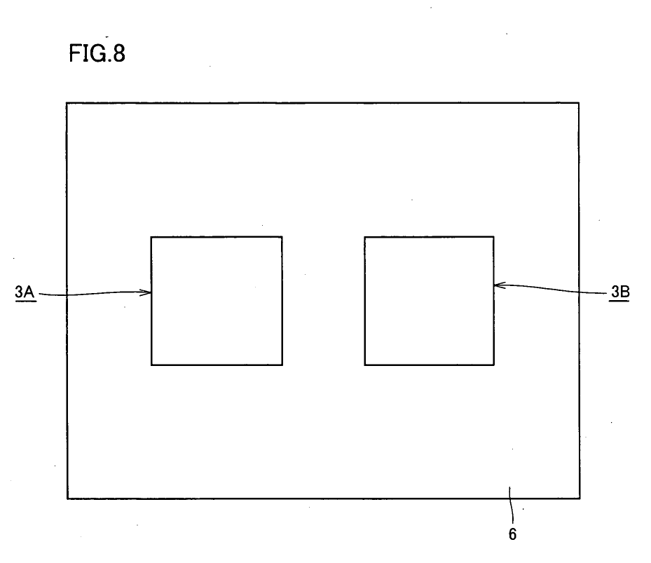

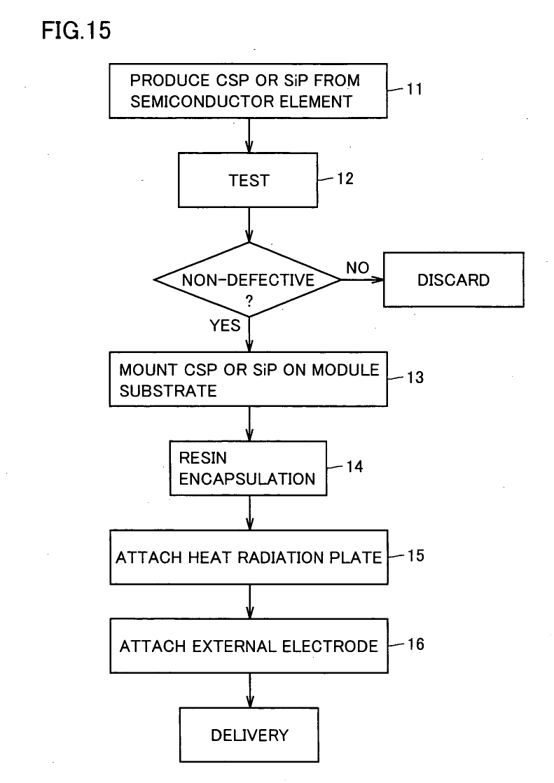

FIG. 6 is a cross section of a semiconductor module according to a first embodiment. FIGS. 1A, 1B to FIG. 5 show respective steps through which the module in FIG. 6 is completed. FIG. 15 shows a flow of a process of manufacturing the semiconductor module shown in FIGS. 1A, 1B to FIG. 6.

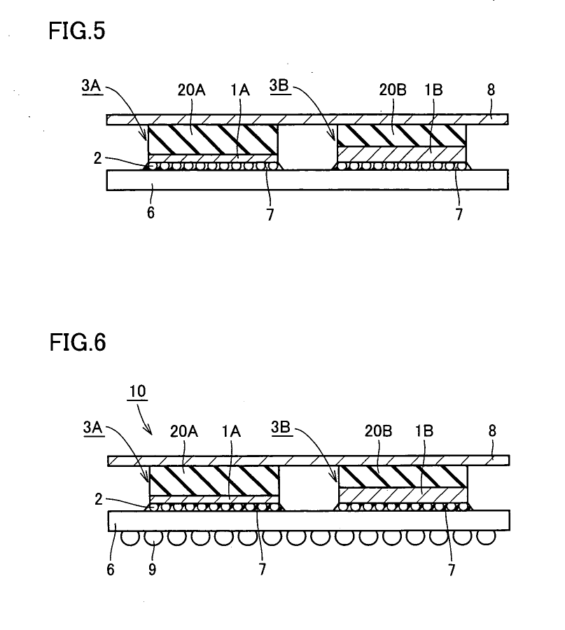

Semiconductor module 10 of this embodiment includes, as shown in FIG. 6, a module substrate 6, an external electrode 9 on the rear surface of module substrate 6, and semiconductor devices 3A, 3B provided on module substrate 6 and having substantially the same thickness t (see FIGS. 2A and 2B). Further, a heat radiation plate 8 is provided on semiconductor devices 3A, 3B.

Semiconductor device 3A (first semiconductor device) includes a semiconductor element 1A (first semiconductor element) mounted via an inner bump 2 on module substrate 6 and a resin portion 20A (first resin portion) having a thickness t3 (see FIG. 2A) on semiconductor element 1A and covering semiconductor element 1A.

Semiconductor device 3B (second semiconductor device) includes a semiconductor element 1B (second semiconductor element) mounted via inner bump 2 on module substrate 6 and a resin portion 20B (second resin portion) having a thickness t4 (see FIG. 2B) on semiconductor element 1B that is different from thickness t3 and covering semiconductor element 1B.

The above-mentioned t3 is larger than t4. Namely, thickness t3 of resin portion 20A located on semiconductor element 1A and thickness t4 of resin portion 20B located on semiconductor element 1B are different from each other.

In FIG. 6, inner bumps 2 (electrodes) are covered with an encapsulating resin 7 (underfill resin) and inner bumps 2 are thus protected from heat during a reflow process.

Each of the steps through which the state shown in FIG. 6 is reached are now described with reference to FIGS. 1A, 1B to FIG. 5.

As shown in FIGS. 1A and 1B, semiconductor elements 1A, 1B (chips) different in thicknesses from each other are prepared. As shown in FIG. 1A, semiconductor element 1A has a thickness t1 (first thickness) and, as shown in FIG. 1B, semiconductor element 1B has a thickness t2 (second thickness). Thickness t1 of semiconductor element 1A is smaller than thickness t2 of semiconductor element 1B. On the rear surface of semiconductor elements 1A, 1B, inner bumps 2 are formed.

As shown in FIGS. 2A and 2B, resin portions 20A, 20B are formed on semiconductor elements 1A, 1B to cover semiconductor elements 1A, 1B respectively. In this way, semiconductor devices 3A, 3B that are CSPs (Chip Scale Packages) are produced (step 11 in FIG. 15).

While semiconductor elements 1A, 1B are different in thickness, semiconductor devices 3A, 3B including resin portions 20A, 20B are substantially equal in thickness to each other. In other words, the different thicknesses (t3, t4) of resin portions 20A, 20B on respective semiconductor elements 1A, 1B allow semiconductor devices 3A, 3B to be substantially identical in thickness (t) to each other.

The thicknesses may be determined so that the conditions t3>0 and t4=0 are satisfied to expose a surface of semiconductor element 1B.

To semiconductor devices 3A, 3B, a DC or AC voltage is applied to test the devices for their electrical characteristics (such as high-frequency characteristics) (step 12 in FIG. 15).

According to the results of the test, devices that satisfy predetermined specifications (those may hereinafter be referred to as non-defective products) undergo following steps. Devices that do not satisfy the predetermined specifications are discarded.

If the above-described test for electrical characteristics is performed on semiconductor module 10 shown in FIG. 6 into which semiconductor devices are assembled, there could be a case in which one of a plurality of semiconductor devices 3A, 3B mounted on module substrate 6 fails to satisfy predetermined specifications and accordingly the whole semiconductor module including other non-defective semiconductor devices 3A, 3B for example has to be discarded.

In contrast, in this embodiment as described above, only non-defective products, i.e., semiconductor devices 3A and 3B are mounted on module substrate 6. Thus, yields of components included in semiconductor devices 3A, 3B as well as module substrate 6 and heat radiation plate 8 for example can be improved as compared with the case in which the test for electrical characteristics is conducted, after assembling, on the semiconductor module.

Moreover, since the test for electrical characteristics is conducted after semiconductor devices 3A and 3B that are CSPs are produced from semiconductor elements 1A, 1B, the test can be facilitated using such an instrument as prober.

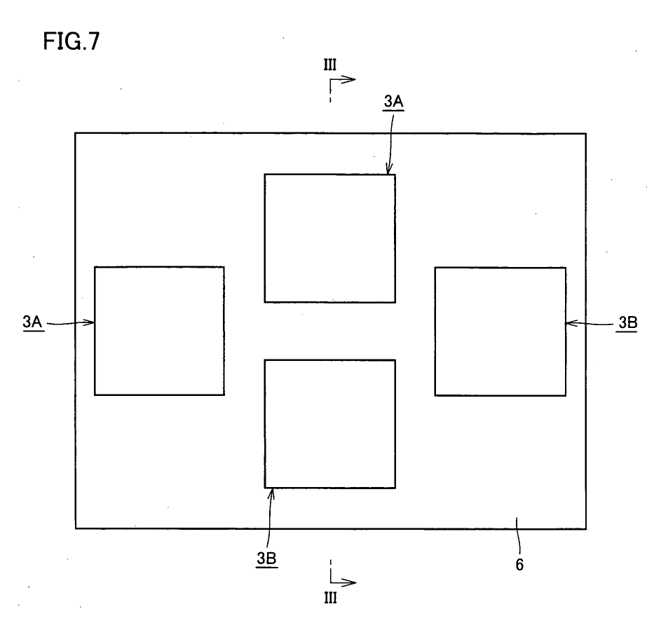

Subsequently, as shown in FIG. 3, a plurality of semiconductor devices 3A, 3B satisfying predetermined specifications are mounted on module substrate 6 (step 13 in FIG. 15).

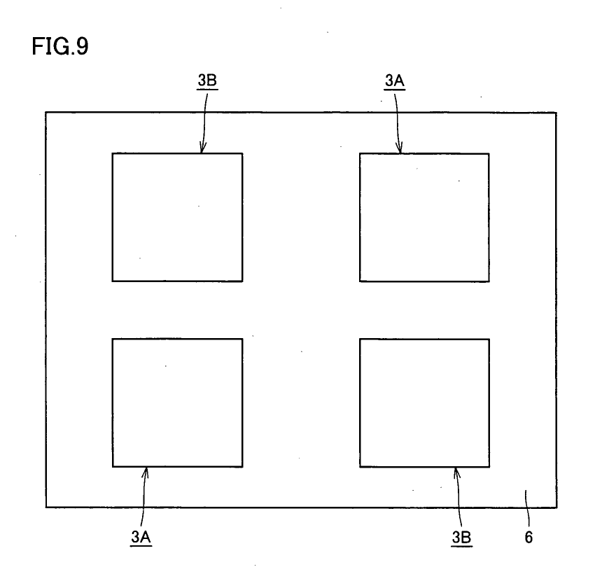

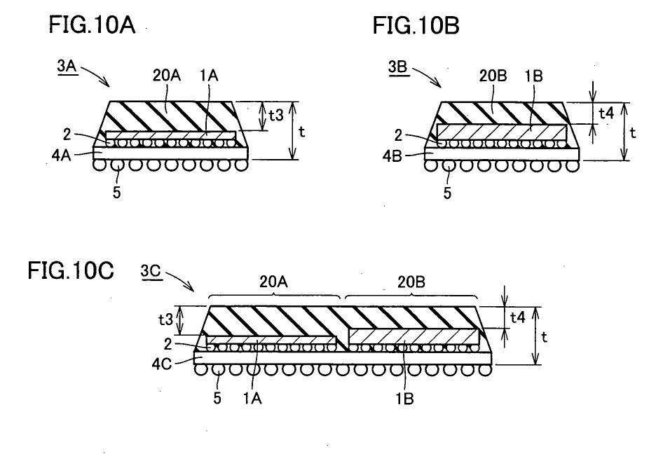

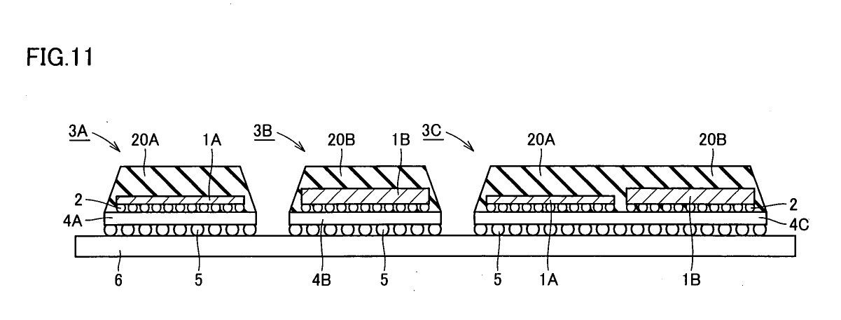

FIG. 7 is a plan view showing an example of the state in FIG. 3. FIG. 3 corresponds to the cross section along III-III in FIG. 7. The arrangement of semiconductor devices 3A, 3B on module substrate 6 is not limited to the arrangement shown in FIG. 7 and may be those shown for example in FIGS. 8 and 9. Semiconductor devices 3A, 3B and interconnections on module substrate 6 are electrically connected via inner bumps 2.

As shown in FIG. 4, preferably inner bumps 2 are covered with encapsulating resin 7 (underfill resin) (step 14 in FIG. 15).

Inner bumps 2 are thus protected from heat during a reflow process.

Since semiconductor devices 3A, 3B generate heat in operation, the heat is radiated preferably by providing heat radiation plate 8 as shown in FIG. 5 on semiconductor devices 3A, 3B (step 15 in FIG. 15).

In FIG. 5, heat radiation plate 8 is provided to extend over semiconductor devices 3A and 3B.

As mentioned above, semiconductor elements 1A, 1B have respective thicknesses (t1, t2) different from each other. Therefore, if resin portions 20A, 20B of substantially the same thickness are formed on semiconductor elements 1A, 1B, semiconductor devices 3A, 3B have respective total thicknesses different from each other. If the thicknesses of semiconductor devices 3A, 3B differ from each other and a semiconductor module in which these devices are provided on module substrate 6 is to be produced, the manufacturing process is complicated due to the necessity for example of separate heat radiation plates 8 according to the difference in thickness between semiconductor devices 3A, 3B.

In contrast, according to this embodiment, resin portions 20A, 20B have different thicknesses so that respective thicknesses of semiconductor devices 3A, 3B having semiconductor elements 1A, 1B of different thicknesses are substantially equal to each other. Thus, a single heat radiation plate 8 may be provided for example to extend over semiconductor devices 3A, 3B. In this way, the manufacturing process of a semiconductor module is simplified.

In the state shown in FIG. 5, external electrodes 9 are provided on the rear surface of module substrate 6 (step 16 in FIG. 15).

Through the steps as detailed above, semiconductor module 10 shown in FIG. 6 is produced. Semiconductor module 10 is electrically connected to external interconnections via external electrodes 9.

The above-discussed method of manufacturing a semiconductor module may briefly be described as follows. The method of manufacturing semiconductor module 10 in accordance with the present embodiment includes the steps of producing semiconductor devices 3A, 3B (first and second semiconductor devices) of substantially the same thickness by forming resin portion 20A (first resin portion) on semiconductor element 1A (first semiconductor element) and forming resin portion 20B (second resin portion) on semiconductor element 1B (second semiconductor element) (FIG. 2), mounting semiconductor devices 3A, 3B on module substrate 6 (FIG. 3), covering inner bumps 2 (electrodes) of semiconductor devices 3A, 3B with encapsulating resin 7 (underfill resin) (FIG. 4), providing heat radiation plate 8 extending over semiconductor devices 3A, 3B (FIG. 5), and providing external electrode 9 on the rear surface of module substrate 6 (FIG. 6).

The simplified process of manufacturing a semiconductor module can thus be provided as described above.

Preferably, before semiconductor devices 3A, 3B are mounted on module substrate 6, a test for electrical characteristics is conducted on each of semiconductor devices 3A, 3B.

Accordingly, only non-defective semiconductor devices 3A, 3B can be mounted on module substrate 6 to improve yields of semiconductor elements and other components in manufacture of semiconductor modules each having a plurality of semiconductor devices mounted thereon.

Although the above description of the present embodiment is for a CSP having one semiconductor element 1 (1A, 1B) that is one form of semiconductor devices 3A, 3B, the form in which semiconductor devices 3 (3A, 3B) are implemented is not limited to the above-described one. For example, such a device as an Sip (System in Package) having above-described CSPs stacked on each other may be employed as semiconductor device 3.

### Second Embodiment

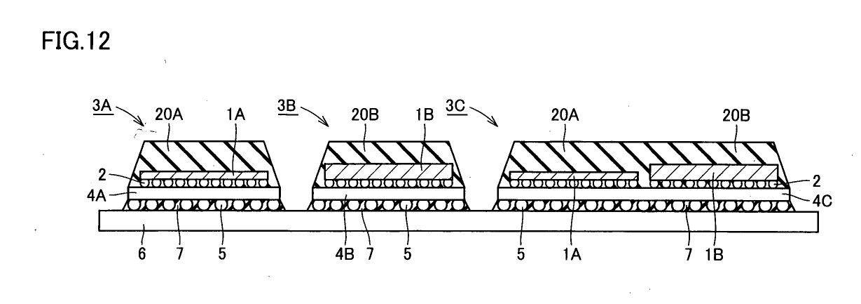

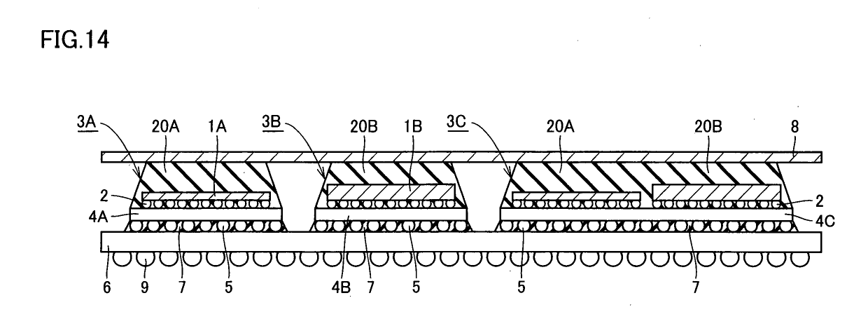

FIG. 14 is a cross section of a semiconductor module according to a second embodiment, and FIGS. 10A, 10B, 10C to FIG. 13 show respective steps through which the semiconductor module shown in FIG. 14 is completed.

The semiconductor module of this embodiment is manufactured following the same flow as that of the first embodiment (see FIG. 15).

Semiconductor module 10 of this embodiment includes, as shown in FIG. 14, a module substrate 6, an external electrode 9 on the rear surface of module substrate 6, and semiconductor devices 3A, 3B, 3C having substantially the same thickness t (see FIGS. 10A to 10C) on module substrate 6. Further, a heat radiation plate 8 is provided on semiconductor devices 3A, 3B, 3C.

Semiconductor device 3A (first semiconductor device) includes a substrate 4A (first substrate) connected via an electrode 5 to module substrate 6, a semiconductor element 1A (first semiconductor element) mounted via an inner bump 2 on substrate 4A and a resin portion 20A (first resin portion) having a thickness t3 (see FIG. 10A) on semiconductor element 1A and covering semiconductor element 1A.

Semiconductor device 3B (second semiconductor device) includes a substrate 4B (second substrate) connected via electrode 5 to module substrate 6, a semiconductor element 1B (second semiconductor element) mounted via inner bump 2 on substrate 4B and a resin portion 20B (second resin portion) having a thickness t4 (see FIG. 10B) on semiconductor element 1B that is different from thickness t3 and covering semiconductor element 1B.

T3 is larger than t4, namely thickness t3 of resin portion 20A located on semiconductor element 1A is different from thickness t4 of resin portion 20B located on semiconductor element 1B.

Semiconductor device 3C (third semiconductor device) includes a substrate 4C (third substrate) connected via electrode 5 to module substrate 6, a semiconductor element 1A (first semiconductor element) mounted via inner bump 2 on substrate 4C, a resin portion 20A (first resin portion) having thickness t3 (see FIG. 10C) on semiconductor element 1A and covering semiconductor element 1A, a semiconductor element 1B (second semiconductor element) mounted via inner bump 2 on substrate 4C, and a resin portion 20B (second resin portion) having thickness t4 on semiconductor element 1B that is different from thickness t3 and covering semiconductor element 1B.

In FIG. 14, electrodes 5 are covered with an encapsulating resin 7 (underfill resin). Thus, electrodes 5 are protected from heat during a reflow process.

Each of the steps through which the state shown in FIG. 14 is reached are described with reference to FIGS. 10A, 10B, 10C to FIG. 13.

Semiconductor elements 1A and 1B (chips) are prepared as done in the first embodiment (see FIGS. 1A and 1B).

Then, as shown in FIGS. 10A to 10C, one or more than one of semiconductor elements 1A, 1B is/are mounted on each of substrates 4A, 4B, 4C. Substrates 4A, 4B, 4C are typically made of the same material and have the same thickness in FIGS. 10A to 10C. Semiconductor elements 1A, 1B and substrates 4A, 4B, 4C are electrically connected via inner bumps 2. Resin portions 20A, 20B are thereafter formed on substrates 4A, 4B, 4C to cover semiconductor elements 1A, 1B respectively. In this way, semiconductor devices 3A, 3B, 3C that are CSPs are produced (step 11 in FIG. 15).

While semiconductor elements 1A, 1B are different in thickness, semiconductor devices 3A, 3B including resin portions 20A, 20B are substantially identical in thickness. In other words, the different thicknesses (t3, t4) of resin portions 20A, 20B on respective semiconductor elements 1A, 1B allow semiconductor devices 3A, 3B, 3C to be substantially identical in thickness (t) to each other.

The thicknesses may be determined so that the conditions t3>0 and t4=0 are satisfied to expose a surface of semiconductor element 1B.

To semiconductor devices 3A, 3B, 3C, a DC or AC voltage is applied to test the devices for their electrical characteristics (such as high-frequency characteristics) (step 12 in FIG. 15).

According to the results of the test, devices determined as non-defective products undergo following steps. Devices except for the non-defective products are discarded.

In this embodiment as well, only non-defective semiconductor devices 3A, 3B, 3C are mounted on module substrate 6. Thus, yields of components included in semiconductor devices 3A, 3B, 3C as well as module substrate 6 and heat radiation plate 8 for example can be improved as compared with a case in which the test for electrical characteristics is conducted, after assembling, on the semiconductor module.

Moreover, since the test for electrical characteristics is conducted after semiconductor devices 3A, 3B, 3C that are CSPs are produced from semiconductor elements 1A and 1B, the test can be facilitated using such an instrument as prober.

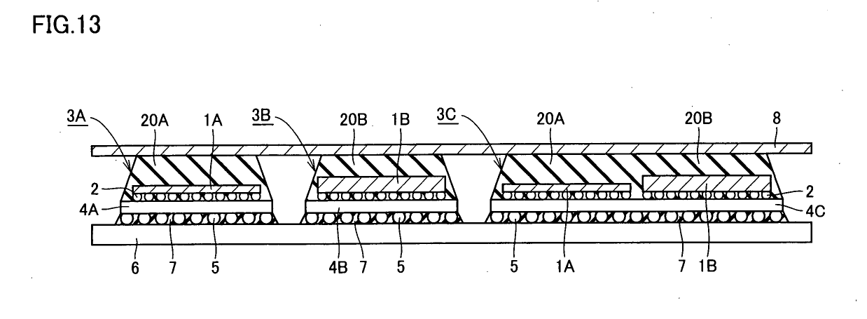

Subsequently, as shown in FIG. 11, semiconductor devices 3A, 3B, 3C satisfying predetermined specifications are mounted on module substrate 6 (step 13 in FIG. 15).

Although one semiconductor device 3A, one semiconductor device 3B and one semiconductor device 3C are mounted on module substrate 6 shown in FIG. 11, the number of devices mounted on the module substrate may appropriately be changed. Semiconductor devices 3A, 3B, 3C and interconnections on module substrate 6 are electrically connected via electrodes 5.

As shown in FIG. 12, preferably electrodes 5 are covered with encapsulating resin 7 (underfill resin) (step 14 in FIG. 15).

Electrodes 5 are thus protected from heat during a reflow process.

Since semiconductor devices 3A, 3B, 3C generate heat during their operation, the heat is radiated preferably by providing heat radiation plate 8 as shown in FIG. 13 on semiconductor devices 3A, 3B, 3C (step 15 in FIG. 15).

In FIG. 13, heat radiation plate 8 is provided to extend over semiconductor devices 3A, 3B, 3C.

In this embodiment as the first embodiment, resin portions 20A and 20B have different thicknesses (t1, t2) so that respective thicknesses of semiconductor devices 3A, 3B, 3C having semiconductor elements 1A and 1B of different thicknesses are substantially equal to each other. Thus, a single heat radiation plate 8 may be provided for example that extends over semiconductor devices 3A, 3B, 3C. In this way, the manufacturing process of a semiconductor module is simplified.

In the state shown in FIG. 13, external electrode 9 is provided on the rear surface of module substrate 6 (step 16 in FIG. 15).

Through the steps as detailed above, semiconductor module 10 shown in FIG. 14 is produced. Semiconductor module 10 is electrically connected to external interconnections via external electrodes 9.

The above-discussed method of manufacturing a semiconductor module may briefly be described as follows. The method of manufacturing semiconductor module 10 in accordance with the present embodiment includes the steps of: mounting semiconductor elements 1A, 1B (first and second semiconductor elements) different in thickness from each other on substrates 4A, 4B, 4C (first to third substrates); forming resin portion 20A (first resin portion) on semiconductor element 1A (first semiconductor element) and forming resin portion 20B (second resin portion) on semiconductor element 1B (second semiconductor element) to produce semiconductor devices 3A, 3B, 3C (first to third semiconductor devices) of substantially the same thickness (FIGS. 10A to 10C); mounting semiconductor devices 3A, 3B, 3C on module substrate 6 (FIG. 11); covering electrodes 5 of semiconductor devices 3A, 3B, 3C with encapsulating resin 7 (underfill resin) (FIG. 12); providing heat radiation plate 8 extending over semiconductor devices 3A, 3B, 3C (FIG. 13); and providing external electrode 9 on the rear surface of module substrate 6 (FIG. 14).

The simplified process of manufacturing a semiconductor module can thus be provided as described above.

Preferably, before semiconductor devices 3A, 3B, 3C are mounted on module substrate 6, a test for electrical characteristics is conducted on each of semiconductor devices 3A, 3B, 3C.

In this way, only non-defective semiconductor devices 3A, 3B, 3C can be mounted on module substrate 6 to improve yields of semiconductor elements and other components in manufacture of semiconductor modules each having a plurality of semiconductor devices mounted thereon.

Moreover, although the above description of this embodiment is for a CSP having one or two semiconductor elements 1 (1A, 1B) that is one form of semiconductor devices 3A, 3B, 3C, the form in which semiconductor devices 3 (3A, 3B, 3C) are implemented is not limited to the above-described one. For example, such a device as an SiP (System in Package) having above-described CSPs stacked on each other may be employed as semiconductor device 3.

It is noted that any appropriate combination of the features/characteristics of the above-described embodiments each is intended to be within the scope of the present invention.

Although the present invention has been described and illustrated in detail, it is clearly understood that the same is by way of illustration and example only and is not to be taken by way of limitation, the spirit and scope of the present invention being limited only by the terms of the appended claims.

1. A method of manufacturing a semiconductor module comprising the steps of:
producing a first semiconductor device by forming a first resin portion on a first semiconductor element;
producing a second semiconductor device substantially identical in thickness to said first semiconductor device by forming a second resin portion on a second semiconductor element different in thickness from said first semiconductor element;
mounting said first semiconductor device and said second semiconductor device on a module substrate; and
providing an external electrode on a rear surface of said module substrate.

2. The method of manufacturing a semiconductor module according to claim 1, wherein
before said first semiconductor device and said second semiconductor device are mounted on said module substrate, a test for electrical characteristics is conducted on each of said first semiconductor device and said second semiconductor device.

3. A semiconductor module comprising:
a module substrate;
an external electrode on a rear surface of said module substrate;
a first semiconductor device having on said module substrate a first semiconductor element with a first thickness and a first resin portion on said first semiconductor element; and
a second semiconductor device substantially identical in thickness to said first semiconductor device and having on said module substrate a second semiconductor element with a second thickness different from said first thickness and a second resin portion on said second semiconductor element.

4. The semiconductor module according to claim 3, wherein
said first resin portion located on said first semiconductor element and said second resin portion located on said second semiconductor element are different in thickness from each other.
